(19) United States
(12) Patent Application Publication
(10) Pub. No.: US 2007/0045873 A1
(43) Pub. Date: Mar. 1, 2007

(54) Semiconductor memory card and method for manufacturing semiconductor memory card

(75) Inventor: Yasuo Takemoto, Yokohama-Shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Minato-ku (JP)

(21) Appl. No.: 11/502,560

(22) Filed: Aug. 11, 2006

(30) Foreign Application Priority Data
Aug. 25, 2005 (JP) 2005-244256

(51) Int. Cl. H01L 23/52

(52) U.S. Cl. 257/784

(57) ABSTRACT

A semiconductor memory card comprises a wiring substrate having input-output terminals for inputting and outputting a signal formed on its topside; a semiconductor memory chip connected to pads formed on a topside or an underside of the wiring substrate; wirings for plating for supplying electric power necessary for electrolytic plating, formed on the wiring substrate and cut at a side edge portion thereof; and a sealing resin for sealing the semiconductor memory chip on the wiring substrate and sealing the side edge portion of the wiring substrate and an end of at least one of the wirings for plating.

### CROSS-REFERENCE TO RELATED APPLICATIONS

This application is based upon and claims the benefit of priority from the prior Japanese Patent Application No. 2005-244256, filed on Aug. 25, 2005, the entire contents of which are incorporated herein by reference.

### BACKGROUND OF THE INVENTION

1. Field of the Invention

The present invention relates to a semiconductor memory card including a sealed wiring substrate and a method for manufacturing the semiconductor memory card.

2. Background Art

In recent years, the semiconductor memory card having a semiconductor memory device embedded therein is widely used as a data storage medium for digital apparatuses such as a digital video camera, a cellular telephone and a portable music player.

The conventional semiconductor memory card may include an insulating cover case (cap) made of polyphenylether, a wiring substrate housed in the cover case and having input-output terminals for inputting and outputting signals provided its topside, a semiconductor memory chip connected via pads provided an underside of the wiring substrate, and a wiring for supplying electric power necessary for electrolytic plating (wiring for plating) formed on the wiring substrate and cut at a side edge portion thereof (refer to Japanese Patent Laid-Open No. 2004-13738 for instance).

According to this conventional technology, the wiring substrate is housed in the cover case, and so product cost rises depending on case cost, manufacturing cost and the like.

In the case where a surface of the wiring substrate having the semiconductor memory chip mounted thereon is sealed with a resin and cut out in a predetermined outer shape like a general semiconductor package for instance to decrease manufacturing cost of the semiconductor memory card by omitting the case, the wiring for plating is exposed at the side edge portion of the wiring substrate. In this case, the wirings for plating may mutually short-circuited by contacting a conductor such as a connector when used, or a noise signal (unnecessary signal) may be inputted to the wiring for plating, which can cause a malfunction of the semiconductor memory card.

In the case where the wiring for plating is removed (etched back) from the wiring substrate after plating for instance to avoid exposure of the wiring for plating at the side edge portion of the wiring substrate, the manufacturing cost becomes higher because the number of processes increases.

In the case where the input-output terminals and the pads are formed by nonelectrolytic plating to avoid the exposure of the wiring for plating at the side edge portion of the wiring substrate, film thickness of a formed film will be thinner than that of the film formed by the electrolytic plating. Therefore, reliability against corrosion and a bondability will be low, and it becomes more expensive than the electrolytic plating when obtaining desired film thickness so that the manufacturing cost consequently becomes higher.

As described above, the conventional technology has a problem that the manufacturing cost of the semiconductor memory card cannot thereby be reduced.

### SUMMARY OF THE INVENTION

According one aspect of the present invention, there is provided: a semiconductor memory card comprising a wiring substrate having input-output terminals for inputting and outputting a signal formed on its topside; a semiconductor memory chip connected to pads formed on a topside or an underside of the wiring substrate; wirings for plating for supplying electric power necessary for electrolytic plating, formed on the wiring substrate and cut at a side edge portion thereof; and a sealing resin for sealing the semiconductor memory chip on the wiring substrate and sealing the side edge portion of the wiring substrate and an end of at least one of the wirings for plating.

According other aspect of the present invention, there is provided: a method for manufacturing a semiconductor memory card comprising supplying electric power by wirings for plating formed on a board for forming a wiring substrate of the semiconductor memory card, to form input-output terminals and pads connected to the wirings for plating on the board by electrolytic plating; forming slits on the board and cutting the wirings for plating; connecting the pads and a semiconductor memory chip by bonding; after the bonding, sealing the semiconductor memory chip and ends of the cut wirings for plating by molding a surface of the board having the semiconductor memory chip provided thereon and a side edge portion of the board having the slits formed thereon with the sealing resin; and cutting the board along a section line for blocking out the wiring substrates of the individual semiconductor memory cards.

### BRIEF DESCRIPTION OF THE DRAWINGS

FIG. 1 is a front view showing a configuration of a substantial part of a semiconductor memory card according to a first embodiment of the present invention;

FIG. 2 is a side edge view of the semiconductor memory card seen from a direction B of FIG. 1;

FIG. 3 is a sectional view showing a cross section of the semiconductor memory card along A-A line of FIG. 1;

FIG. 4 is a diagram showing the process of the method for manufacturing the semiconductor memory card according to the first embodiment which is an aspect of the present invention;

FIG. 5 is a diagram showing the process of the method for manufacturing the semiconductor memory card according to the first embodiment which is an aspect of the present invention;

FIG. 6 is a diagram showing the process of the method for manufacturing the semiconductor memory card according to the first embodiment which is an aspect of the present invention;

FIG. 7 is a diagram showing the process of the method for manufacturing the semiconductor memory card according to the first embodiment which is an aspect of the present invention;

FIG. 8 is a front view showing a configuration of a substantial part of other semiconductor memory card according to a first embodiment of the present invention; and

FIG. 9 is a front view showing a configuration of a substantial part of other semiconductor memory card according to a first embodiment of the present invention.

### DETAILED DESCRIPTION

The present invention eliminates a cover case of a semiconductor memory card and seals a portion having exposed wirings for plating with a resin and thereby prevents input and output of a noise signal from the wirings for plating and mutual short-circuiting of the wirings for plating.

Thus, by eliminating the cover case and forming input-output terminals and pads by means of electrolytic plating without taking expensive measures such as etch back, manufacturing cost of the semiconductor memory card will be reduced.

Hereunder, embodiments to which the present invention is applied will be described with reference to the drawings.

### First Embodiment

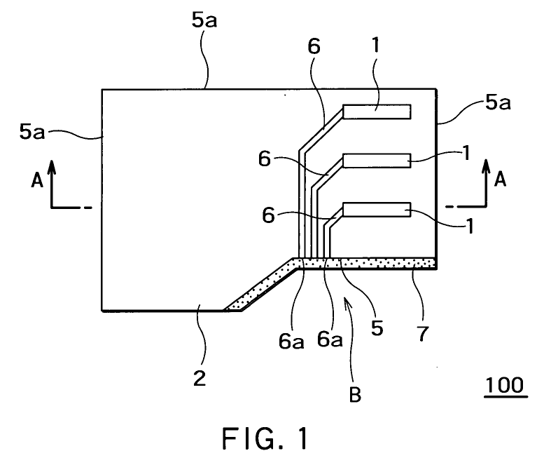

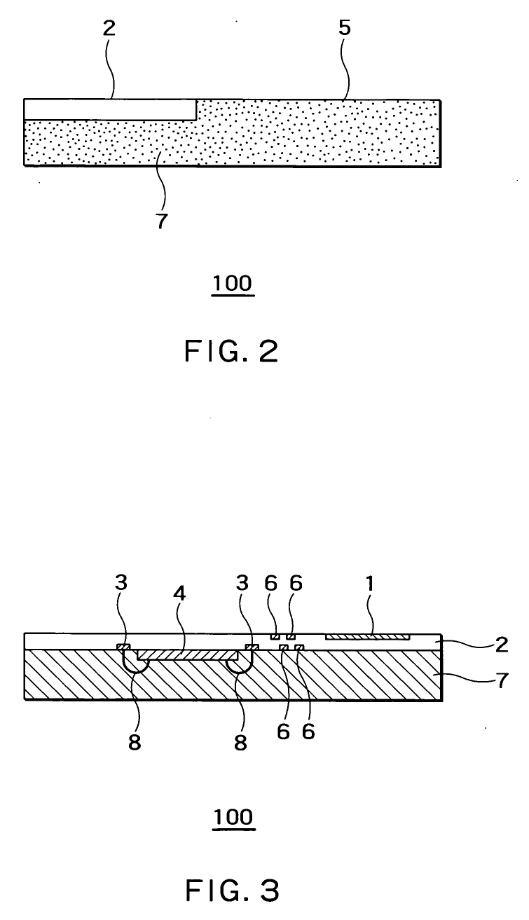

FIG. 1 is a front view showing a configuration of a substantial part of a semiconductor memory card according to a first embodiment of the present invention. FIG. 2 is a side edge view of the semiconductor memory card seen from a direction B of FIG. 1. FIG. 3 is a sectional view showing a cross section of the semiconductor memory card along A-A line of FIG. 1. In these drawings, wirings other than the wiring for plating are omitted therefrom for the sake of simplification.

As shown in FIGS. 1 and 3, a semiconductor memory card 100 includes a wiring substrate 2 having input-output terminals 1 for inputting and outputting a signal formed on its topside, a semiconductor memory chip 4 connected to pads 3 formed on an underside of the wiring substrate 2, and wirings for plating 6 for supplying electric power necessary for the electrolytic plating, formed on the wiring substrate 2 and cut at a side edge portion 5 of the wiring substrate 2, and a sealing resin 7 for sealing the semiconductor memory chip 4 on the wiring substrate 2 and sealing a side edge portion 5 of the wiring substrate 2 and ends 6a of the wirings for plating 6.

The topside of the wiring substrate 2 is coated by a solder resist (not shown) for instance, and the wiring for plating 6 on the topside is insulated from outside.

The semiconductor memory chip 4 is wire-bonded, and is electrically connected to the pads 3 by bonding wires 8. The semiconductor memory chip 4 may also be wirelessly bonded and electrically connected to the pads 3.

The side edge portion 5 is a part of a slit formed on a board (not shown) by stamping it out with a press die for instance before the wiring substrate 2 is cut out of the board by dicing. Thus, the side edge portion 5 is formed by press working so that it can be easily formed into a polygonal structure (form) or a curved structure (form) unlike a linear portion shown in FIG. 1. The wirings for plating 6 are cut the press working. A side edge portion 5a linearly cut by dicing is not sealed by the sealing resin 7.

The wirings for plating 6 are connected to the input-output terminals 1 and the pads 3 which should undergo the electrolytic plating respectively. The wirings for plating 6 are used to supply electric power necessary for the electrolytic plating applied from outside so as to form the respective input-output terminals 1 and the pads 3 by nickel-gold plating before the slit is formed on the board (not shown).

As previously described, the sealing resin 7 seals the ends 6a of the wirings for plating 6 connected to the input-output terminals 1 and also seals the ends 6a of the wirings for plating 6 connected to the pads 3. Thus, the sealed portions can avoid short-circuiting with another wiring and the like and input of a noise signal.

Next, a description will be given as to a method for manufacturing the semiconductor memory card 100 having the structure. The manufacturing method is characterized in that the slit hardly formable by dicing is formed by press working on the board on which the wiring substrates 2 are formed, and the portions stamped out by press working including the wirings for plating 6 are sealed by the sealing resin 7 and separated the wiring substrates 2 by dicing thereafter.

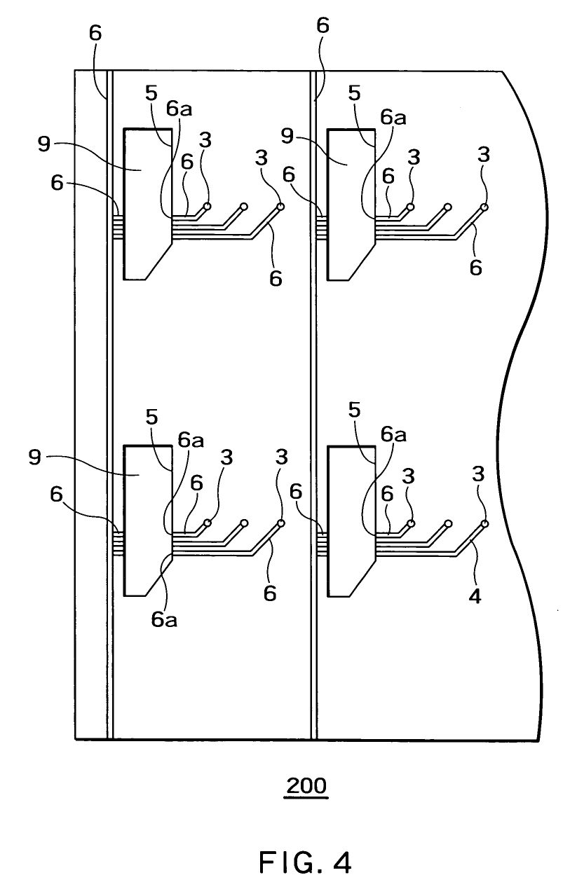

Hereunder, the manufacturing method will be described in detail with reference to the drawings. FIGS. 4 to 7 are diagrams showing the processes of the method for manufacturing the semiconductor memory card according to the first embodiment which is an aspect of the present invention. These diagrams refer to the underside of the wiring substrate 2 (that is, the underside of the board) having the semiconductor memory chip 4 (not shown) connected thereto and sealed by the sealing resin 7 for the sake of description. Furthermore, FIGS. 4 to 7, the semiconductor memory chip and bonding wires are omitted for the sake of simplification.

First, the wirings for plating 6 formed on a board 200 for forming the wiring substrate 2 of the semiconductor memory card 100 are used to supply the electric power necessary for the electrolytic plating applied from outside so as to form the pads 3 having the wirings for plating 6 connected thereto by the electrolytic plating on the board 200. Similarly, the input-output terminals 1 are formed on the top side of the board 200 by the electrolytic plating. The press die is used to cut the wirings for plating 6 and form slits 9 on the board 200 (FIG. 4).

Next, the pads 3 are connected to the semiconductor memory chip 4 by bonding. After the bonding, the underside provided with the semiconductor memory chip 4 of the board 200 and the side edge portions 5 of the board 200 having the slits 9 formed thereon are molded by the sealing resin 7.

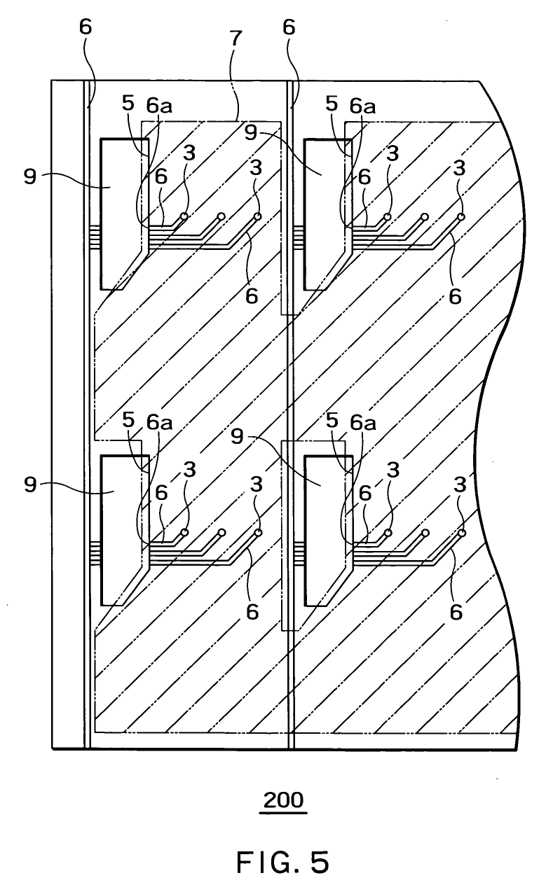

Thus, the semiconductor memory chip 4 is sealed, and the ends 6a of the cut wirings for plating 6 are also sealed (FIG. 5).

When molding a resin, the board 200 is pressed by a molding die (not shown) defining an outer edge of the sealing resin 7. Therefore, it is possible to prevent the board 200 from becoming distorted and the sealing resin 7 from coming around to the topside thereof and also prevent the wirings, bonding wires and the like from becoming deformed.

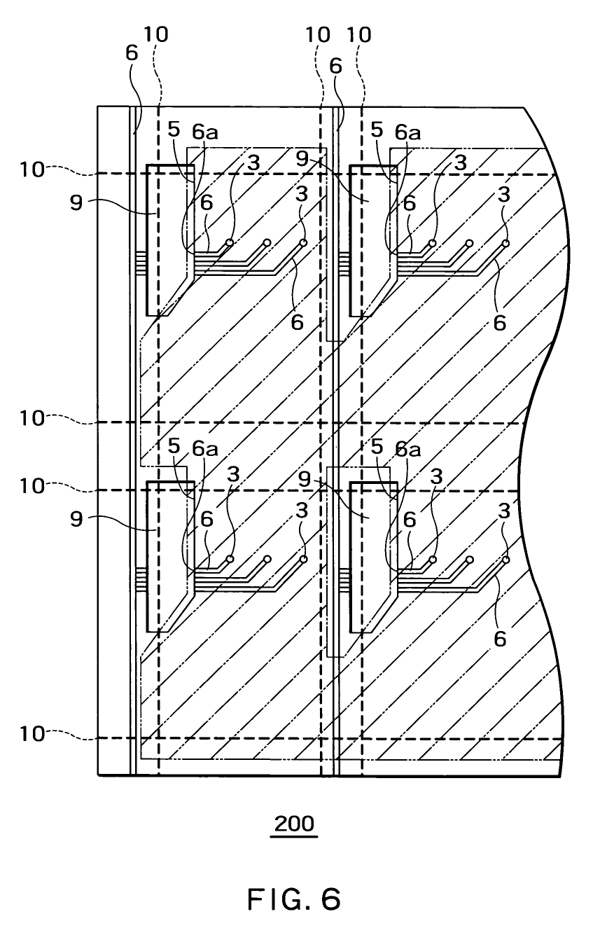

Next, the dicing is performed to the board 200 along a section line 10 for blocking out the wiring substrates of individual semiconductor memory cards (FIG. 6).

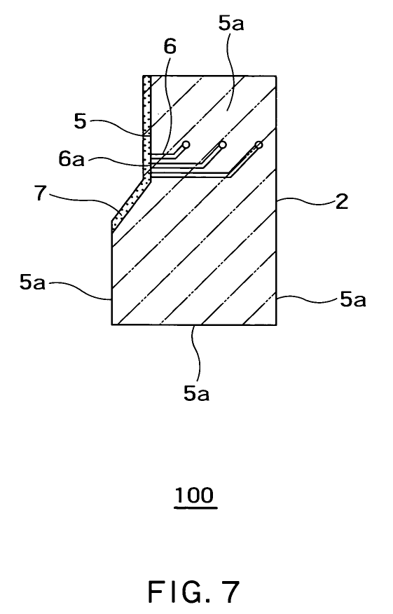

The board 200 is divided by the dicing into the individual wiring substrates 2 (semiconductor memory cards 100) (FIG. 7). The topside of the semiconductor memory card 100 in FIG. 7 has a configuration shown in FIG. 1.

Thus, the side edge portion 5 having a complicated cut structure is formed by press working and sealed with the resin, and the linear side edge portion 5a is formed by cutting it through dicing, and so the outer edge of the semiconductor memory card 100 can be easily formed so as to reduce the manufacturing cost.

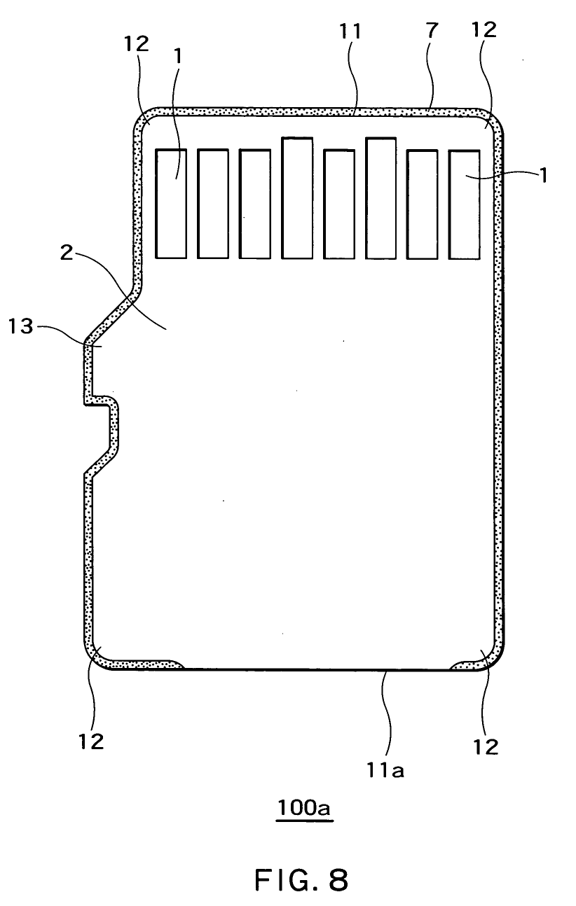

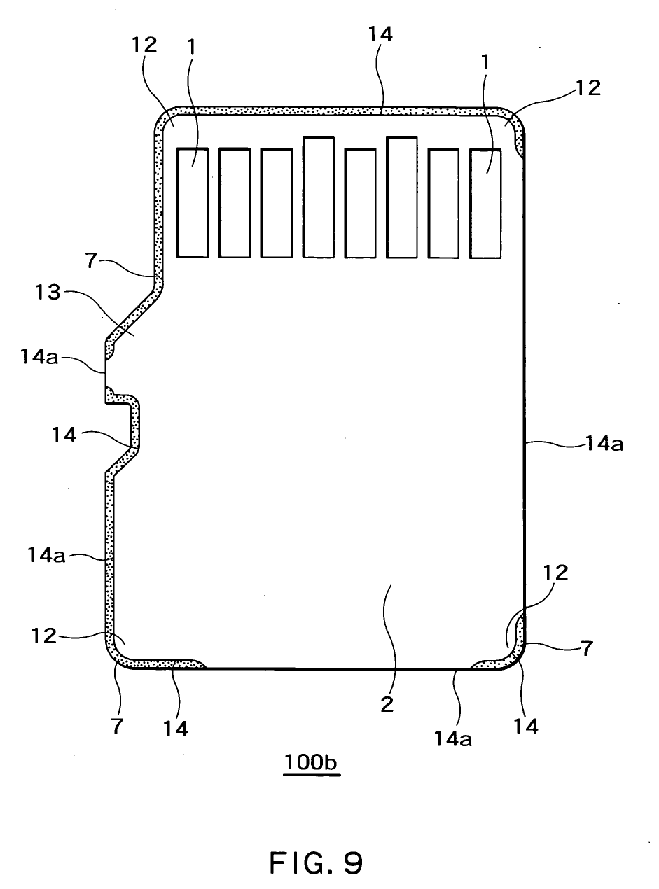

FIGS. 8 and 9 show other examples manufactured by the method for manufacturing the semiconductor memory card.

As shown in FIG. 8, a semiconductor memory card 100a has a side edge portion 11a formed by dicing on one of the sides surrounding the wiring substrate 2, and also has a side edge portion 11 formed by press working in the portions including four corners 12 of the wiring substrate 2 and a curved portion of a stopper portion 13 for preventing erroneous insertion into an external device.

Thus, it is possible to form the wiring substrate 2 into a desired form easily by forming by press working a shape with rounded corners, a shape of a stopper and the like which are hardly formable by dicing.

It is also possible, as with a semiconductor memory card 100b shown in FIG. 9, to form side edge portions 14 by press working as to the corners 12 and the stopper portion 13 and connect some of the linear portions surrounding the wiring substrate 2 to the board so as to form side edge portions 14a by cutting the connections through dicing after molding the resin for the sake of enhancing the effect of preventing the board from becoming distorted and the sealing resin from coming around to the opposite side when molding the resin.

As described above, according to the semiconductor memory card of this embodiment, it is possible to eliminate the cover case and form the input-output terminals and the pads by means of the electrolytic plating without taking expensive measures such as etch back so as to cut manufacturing cost of the semiconductor memory card.

This embodiment describes the case of sealing the ends of the wirings for plating wired on the pads for bonding and connecting the input-output terminals and the semiconductor memory chip at the side edge portions of the wiring substrate. However, the same effect can be produced by sealing the ends of the wirings for plating connected to other terminals and pads at the side edge portions of the wiring substrate.

This embodiment also describes the case of sealing the ends of all the wirings for plating connected to the pads for bonding and connecting the input-output terminals and the semiconductor memory chip with the sealing resin. It is also possible, however, to selectively seal the wiring for plating which can cause a malfunction of the semiconductor memory card by contacting another wiring and the like with the sealing resin.

This embodiment also describes that the nickel-gold plating is film-formed by the electrolytic plating. However, it is also applicable to the case of using another material capable of the electrolytic plating such as copper.

This embodiment also describes the case of forming the pads on the underside of the wiring substrate and connecting the semiconductor memory chip by bonding. It is also possible, however, to form the pads on the topside of the wiring substrate and connect the semiconductor memory chip by bonding.

What is claimed is:

1. A semiconductor memory card comprising:
a wiring substrate having input-output terminals for inputting and outputting a signal formed on its topside;
a semiconductor memory chip connected to pads formed on a topside or an underside of the wiring substrate;
wirings for plating for supplying electric power necessary for electrolytic plating, formed on the wiring substrate and cut at a side edge portion thereof; and
a sealing resin for sealing the semiconductor memory chip on the wiring substrate and sealing the side edge portion of the wiring substrate and an end of at least one of the wirings for plating.

2. The semiconductor memory card according to claim 1, wherein the wirings for plating are at least connected to the input-output terminals.

3. The semiconductor memory card according to claim 1, wherein the wirings for plating are at least connected to the pads.

4. The semiconductor memory card according to claim 1, wherein the side edge portion of the wiring substrate sealed by the sealing resin has a curved shape.

5. The semiconductor memory card according to claim 4, wherein the side edge portion of the wiring substrate is formed by press working.

6. The semiconductor memory card according to claim 5, wherein the wirings for plating are cut by the press working.

7. The semiconductor memory card according to claim 6, wherein a stopper portion for preventing erroneous insertion is provided on the wiring substrate by the press working.

8. The semiconductor memory card according to claim 5, wherein another side edge portion of the wiring substrate is cut by dicing.

9. The semiconductor memory card according to claim 2, wherein the input-output terminals are nickel-gold plated.

10. The semiconductor memory card according to claim 3, wherein the pads are nickel-gold plated.

11. A method for manufacturing a semiconductor memory card comprising:
supplying electric power by wirings for plating formed on a board for forming a wiring substrate of the semiconductor memory card, to form input-output terminals and pads connected to the wirings for plating on the board by electrolytic plating;
forming slits on the board and cutting the wirings for plating;
connecting the pads and a semiconductor memory chip by bonding;
after the bonding, sealing the semiconductor memory chip and ends of the cut wirings for plating by molding a surface of the board having the semiconductor memory chip provided thereon and a side edge portion of the board having the slits formed thereon with the sealing resin; and
cutting the board along a section line for blocking out the wiring substrates of the individual semiconductor memory cards.

12. The method for manufacturing a semiconductor memory card according to claim 11, wherein slits are formed on the board and the wirings for plating are cut by press working.

13. The method for manufacturing a semiconductor memory card according to claim 12, wherein a polygonal portion and a curved portion of the wiring substrate are formed by the press working.

14. The method for manufacturing a semiconductor memory card according to claim 13, wherein a stopper portion for preventing erroneous insertion is formed on the wiring substrate by the press working.

15. The method for manufacturing a semiconductor memory card according to claim 12, wherein the board is cut along the section line by dicing.

16. The method for manufacturing a semiconductor memory card according to claim 11, wherein the input-output terminals are nickel-gold plated by the electrolytic plating.

17. The method for manufacturing a semiconductor memory card according to claim 11, wherein the pads are nickel-gold plated by the electrolytic plating.
